(19) United States
(12) Patent Application Publication
(10) Pub. No.: US 2026/0360275 A1
(43) Pub. Date: Nov. 12, 2026

(54) Engineering Study Use of Simulators

(71) Applicant: The Boeing Company, Arlington, VA (US)

(72) Inventors: Brian David Gilbert, Kenmore, WA (US); Nathan C. Dudley, Mercer Island, WA (US)

(21) Appl. No.: 19/203,419

(22) Filed: May 9, 2025

(51) Int. Cl. G09B 9/08; G06F 30/15

(52) U.S. Cl. CPC G09B 9/08; G06F 30/15

(57) ABSTRACT

A method for collecting engineering data. A simulation data stream output from a simulation of an aircraft is received. A number of desired dynamic properties of a physical engineering control in the simulation is identified from the simulation data stream. A physical training control in a training simulator that is an equivalent of the physical engineering control is identified. A number of current dynamic properties is determined for the physical training control. Commands are sent to the physical training control using a difference between the number of current dynamic properties and the number of desired dynamic properties and a feedback controller. Engineering data is collected from the training simulator running of the simulation.

### BACKGROUND INFORMATION

### 1. Field

The present disclosure relates generally to aircraft and in particular, to simulation systems used to collect engineering data.

### 2.Background

A simulator is a physical hardware system operated by a human operator such as a pilot or other person. This simulator is the hardware providing an interface to the pilot or other human operator of the simulator. This hardware can include control inputs such as a yoke, pedals, a throttle, and other controls. The hardware also includes displays such as instruments, heads up displays, and multifunction displays. Other hardware can also include audio and motion systems. This hardware also includes interfaces to the computer or computers that run the simulations presented through the simulator to the pilot.

Simulators are used in collecting engineering data to support design validation, system development, performance analysis, and safety assessment. The use of simulators in collecting engineering data can be performed in a controlled repeatable environment.

The engineering data collected using simulators includes flight dynamics data. This data includes aircraft attitude, position, velocity, acceleration, and other flight parameters. This data can be used to determine the response to control inputs made by pilots during different flight conditions. This type of data can be used to validate and modify designs for aircraft systems.

The engineering data can also include human operator data. This type of data can include, for example, inputs generated by pilots manipulating controls in the simulator. This type of data can provide information about pilot behaviors and reaction times. This data can be used to analyze ergonomics and workloads. Further, the data can be used to determine whether a particular aircraft design provides desired situational awareness of different scenarios and desired responses to those scenarios.

### SUMMARY

An embodiment of the present disclosure provides an engineering simulation system that comprises a computer system and a flight deck evaluation manager which is located in the computer system. The flight deck evaluation manager performs operations. The flight deck evaluation manager receives a simulation data stream output from simulation of an aircraft. The flight deck evaluation manager identifies a number of desired dynamic properties of a physical engineering control in the simulation from the simulation data stream. The flight deck evaluation manager identifies a physical training control in a training simulator that is an equivalent of the physical engineering control. The flight deck evaluation manager determines a number of current dynamic properties for the physical training control. The flight deck evaluation manager sends commands to the physical training control using a difference between the number of current dynamic properties and the number of desired dynamic properties and a feedback controller. The flight deck evaluation manager collects engineering data from the training simulator running of the simulation.

Another embodiment of the present disclosure provides a method for collecting engineering data. A simulation data stream output from a simulation of an aircraft is received. A number of desired dynamic properties of a physical engineering control in the simulation is identified from the simulation data stream. A physical training control in a training simulator that is an equivalent of the physical engineering control is identified. A number of current dynamic properties is determined for the physical training control. Commands are sent to the physical training control using a difference between the number of current dynamic properties and the number of desired dynamic properties and a feedback controller. Engineering data is collected from the training simulator running of the simulation.

Another embodiment of the present disclosure provides a computer program product for collecting engineering data. The computer program product comprises a computer-readable storage medium having program instructions embodied therewith. The program instructions are executable by a computer system to cause the computer system to perform operations. The computer system receives a simulation data stream output from a simulation of an aircraft. The computer system identifies a number of desired dynamic properties of a physical engineering control in the simulation from the simulation data stream. The computer system identifies a physical training control in a training simulator that is an equivalent of the physical engineering control. The computer system determines a number of current dynamic properties for the physical training control. The computer system sends commands to the physical training control using a difference between the number of current dynamic properties and the number of desired dynamic properties and a feedback controller. The computer system collects the engineering data from the training simulator running of the simulation.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is a pictorial representation of a network of data processing systems in which illustrative embodiments may be implemented;

FIG. 2 is an illustration of a block diagram of a simulation environment in accordance with an illustrative embodiment;

FIG. 3 is an illustration of data flow used to control a training hardware controller in accordance with an illustrative embodiment;

FIG. 4 is an illustration of training simulators in accordance with an illustrative embodiment;

FIG. 5 is an illustration of an engineering simulation system and a training simulator in accordance with an illustrative embodiment;

FIG. 6 is an illustration of a dataflow for controlling physical training controls in accordance with an illustrative embodiment;

FIG. 7 is an illustration of a dataflow for controlling a throttle in accordance with an illustrative embodiment;

FIG. 8 is an illustration of a flowchart of a process for controlling movement of a throttle in accordance with an illustrative environment;

FIG. 9 is an illustration of a dataflow for controlling a speed brake control in accordance with an illustrative embodiment;

FIG. 10 is an illustration of a flowchart of a process for collecting engineering data in accordance with an illustrative embodiment;

FIG. 11 is an illustration of a flowchart of a process for collecting engineering data in accordance with an illustrative embodiment;

FIG. 12 is an illustration of a flowchart of a process for analyzing engineering data in accordance with an illustrative embodiment;

FIG. 13 is an illustration of a flowchart of a process for sending commands to a simulator in accordance with an illustrative embodiment;

FIG. 14 is an illustration of a flowchart of a process for sending commands in accordance with an illustrative embodiment;

FIG. 15 is an illustration of a block diagram of a data processing system in accordance with an illustrative embodiment;

FIG. 16 is an illustration of a block diagram of an aircraft manufacturing and service method in accordance with an illustrative embodiment; and

FIG. 17 is an illustration of a block diagram of an aircraft in which an illustrative embodiment may be implemented.

### DETAILED DESCRIPTION

The illustrative embodiments recognize and take into account one or more different considerations as described herein. Engineering simulators used to gather engineering data for analysis and development are different from training simulators for training pilots. These engineering simulators gather data for analysis and have different features from training simulators used for training purposes.

For example, engineering simulators require accurate physics based models that include detailed flight dynamics, control laws, sensor models, and system interactions. In contrast, training simulators focus on realistic but pre-validated behaviors for training pilots. These types of simulators are often simplified for real time performance with perceptual accuracy over physical detail. As a result, the manner in which hardware is controlled can be different between running simulations for engineering purposes and training purposes.

Hardware for simulators can take a number of different forms such as flight training devices (FTDs) and full flight simulators (FFSs). A full flight simulator typically includes a full motion platform, background visuals, and a full replica of the actual flight deck. This type of simulator can provide full simulation of the flight of the aircraft and its systems. A flight training device typically does not have motion and may have limited visual systems and partially replicated flight controls. This type of simulator can provide partial systems for procedural training.

Currently, training simulators can be found at many locations for airlines and third-party training organizations. However, engineering simulators are less prevalent. As a result, obtaining training data from a wide variety of pilots at different locations can be difficult with the limited distribution of engineering simulators.

Although the hardware in training simulators can provide a realistic simulation of flight deck systems and visuals, the simulation software does not enable gathering engineering data for analysis. For example, current simulation software for training simulators often simplifies the performance of the aircraft with an emphasis on perceptual accuracy over physical or actual performance accuracy. The software for engineering simulations are physics based models that accurately simulate the performance of an aircraft. This type of simulation is necessary in obtaining engineering data about the performance of the aircraft and to determine whether pilot responses to that performance are accurate. As a result, a simplification of the performance of an aircraft may not result in a pilot providing accurate responses in response to changes or modifications that are being tested in a simulation.

For example, human factors engineering data is collected that includes the response of a pilot to various scenarios presented through a simulator. These scenarios need to be happening when presented using physics based simulations as compared to simpler simulations often used for training pilots. For example, flight controls, propulsion, landing gear, and other systems need to be actively presented in the simulation to obtain accurate responses from the pilots.

Changes to the systems can include displays and crew alerting (DCA) and flight management (FM). The displays are selected to provide the same fidelity as the actual physical systems. In these examples, fidelity in these simulations means the physical control used in a simulator replicates the behavior, responses, and conditions of the real-world physical control in a flight deck that it represents. High fidelity means a close match in terms of physical characteristics, dynamics, sensory outputs, and operational responses under various conditions.

For example, the display of messages, indications, or other information are selected to not have more latency as compared to the actual systems in the flight deck of an aircraft. As another example, the systems provide the same visual look and feel as the actual systems in order to obtain accurate engineering data with respect to human interface responses of pilots.

In one example, changes may be made to minimize pilot distraction. These changes may be minor and the presentation of these changes in a simulation are made with a sufficient level of fidelity such that human factors testing is accurate. In other words, the simulation replicates the real world system that the simulation is designed to emulate.

However, simulations generated by training software for training may provide a feel for an actual aircraft that is sufficient for training but does not provide all of the information needed to simulate different situations involving the real world system.

As another example, a simulation may include a fault insertion system (FIS) that introduces a malfunction to determine how a pilot reacts to that malfunction. For example, an engine indication of reduced thrust during a takeoff may be introduced during the simulation to determine the response of a pilot. In other words, the simulator gathers engineering data that includes the pilot response to this situation. The pilot response can be to take off or to reject the takeoff. The presentation of the indication and other information in the simulator needs to have sufficient fidelity such that an accurate response occurs.

As another example, a scenario may include taking off during cold weather in which the oil temperature is lower than desired. The airplane startup time and taxi length may be shorter and the pilot is asked to take off in this situation. As a result, the engine thrust may be limited by the cold oil temperature. In the simulation, the engineering data includes the response of the pilot to this scenario. The fidelity of the information presented to the pilot needs to have a high net fidelity such that the response of the pilot is an accurate one.

Currently, training systems may present simulations with a low fidelity that is sufficient to train pilots for particular scenarios, procedures, or situations. However, these training systems can have less fidelity than needed to have a level of confidence in the data being collected for analysis of a design. Lower levels of fidelity in the presentation of a simulation in a simulator can result in distractions or incorrect responses by a human operator during testing of different designs in the simulator.

Thus, the illustrative examples provide a method, apparatus, system, and computer program product for collecting engineering data. For example, an engineering simulation system comprises a computer system and a flight deck evaluation manager which is located in the computer system. The flight deck evaluation manager performs operations. The flight deck evaluation manager receives a simulation data stream output from an aircraft simulation. The flight deck evaluation manager identifies a number of desired dynamic properties of a physical engineering control in the simulation from the simulation data stream. The flight deck evaluation manager identifies a physical training control in a training simulator that is an equivalent of the physical engineering control. The flight deck evaluation manager determines a number of current dynamic properties for the physical training control. The flight deck evaluation manager sends commands to the physical training control using a difference between the number of current dynamic properties and the number of desired dynamic properties and a feedback controller. The flight deck evaluation manager collects the engineering data from the training simulator running of the simulation.

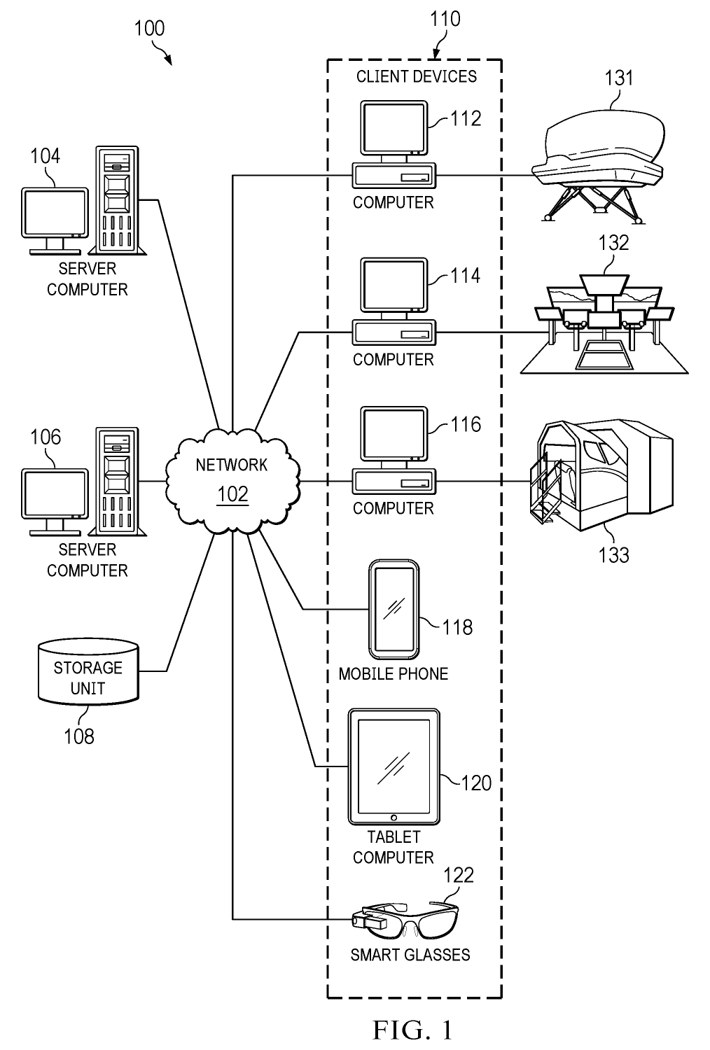

With reference now to the figures and, in particular, with reference to FIG. 1, a pictorial representation of a network of data processing systems is depicted in which illustrative embodiments may be implemented. Network data processing system 100 is a network of computers in which the illustrative embodiments may be implemented. Network data processing system 100 contains network 102, which is the medium used to provide communications links between various devices and computers connected together within network data processing system 100. Network 102 may include connections, such as wired, wireless communication links, or fiber optic cables.

In the depicted example, server computer 104 and server computer 106 connect to network 102 along with storage unit 108. In addition, client devices 110 connect to network 102. Client devices 110 can be, for example, computers, workstations, network computers, vehicles, machinery, appliances, or other devices that can process data. As depicted, client devices 110 include computer 112, computer 114, computer 116, mobile phone 118, tablet computer 120, and smart glasses 122. Client devices 110 can be, for example, computers, workstations, or network computers. In the depicted example, server computer 104 provides information, such as boot files, operating system images, and applications to client devices 110.

In the depicted example, server computer 104 provides information, such as boot files, operating system images, and applications to client devices 110. Further, in this illustrative example, server computer 104, server computer 106, storage unit 108, and client devices 110 are network devices that connect to network 102 in which network 102 is the communications media for these network devices. Some or all of client devices 110 may form an Internet of Things (IoT) in which these physical devices can connect to network 102 and exchange information with each other over network 102.

Client devices 110 are clients to server computer 104 in this example. Network data processing system 100 may include additional server computers, client computers, and other devices not shown. Client devices 110 connect to network 102 utilizing at least one of wired, optical fiber, or wireless connections.

Program instructions located in network data processing system 100 can be stored on a computer-recordable storage medium and downloaded to a data processing system or other device for use. For example, program instructions can be stored on a computer-recordable storage medium on server computer 104 and downloaded to client devices 110 over network 102 for use on client devices 110.

In this illustrative example, computer 112 runs a simulation for training simulator 131. Computer 114 runs a simulation for training simulator 132, and computer 114 runs a simulation for training simulator 133. In this example, training simulator 131 and training simulator 133 are full flight simulators. Training simulator 132 is a full flight training device. These simulators are in different geographic locations. For example, the simulators can be in different rooms, buildings, cities, states, or countries.

These training simulators are typically designed to run simulations for training purposes. In the illustrative example, computer 112 includes software for running engineering simulations even though training simulator 131 is designed for training simulations. As another example, computer 114 can include software for running engineering simulations using training simulator 132, and computer 116 can include software for running engineering simulations using training simulator 133.

In this example, these computers replace computers normally used to run training simulations. In other examples, the software needed for engineering simulations can also be located in the same computer as those used for training simulations.

The engineering simulations run on these training simulators and can be used to evaluate designs for the flight deck of an aircraft. The ability to use these training simulators to perform engineering simulations increases the ability to increase the number of pilots that test these designs as compared to relying on pilots to come to a limited number of locations with engineering simulators.

In these illustrative examples, the engineering simulation software includes software interfaces that enable the simulation to be run using training simulator hardware. This engineering simulation software includes the simulation software and middleware interfaces needed to run the simulations on the training simulators.

In these examples, the engineering simulation software also includes a flight deck evaluation system that operates to control the physical controls in the simulators. This control of the physical controls includes setting commands and other information to the physical controls that cause these controls to move or haptic feedback, or other feedback that has physical or actual performance accuracy. In other words, a flight deck evaluation system ensures that the simulation generated by the engineering simulation software accurately simulates the performance of an aircraft, and not just from a perception for training, when viewed. This type of simulation is used to obtain engineering data about the performance of the aircraft and to determine whether pilot responses to that performance are accurate.

In this example, the engineering data collected by computer 112, computer 114, and computer 116 can be sent to server computer 104 for storage and analysis. Also, scenarios for engineering simulations can be stored in server computer 104 and distributed to computer 112, computer 114, and computer 116 for use in engineering simulations presented on the simulators to collect engineering data to evaluate designs for aircraft.

In the depicted example, network data processing system 100 is the Internet with network 102 representing a worldwide collection of networks and gateways that use the Transmission Control Protocol/Internet Protocol (TCP/IP) suite of protocols or other networking protocols to communicate with one another. At the heart of the Internet is a backbone of high-speed data communication lines between major nodes or host computers consisting of thousands of commercial, governmental, educational, and other computer systems that route data and messages. Of course, network data processing system 100 also may be implemented using a number of different types of networks. For example, network 102 can be comprised of at least one of the Internet, an intranet, a local area network (LAN), a metropolitan area network (MAN), or a wide area network (WAN). FIG. 1 is intended as an example, and not as an architectural limitation for the different illustrative embodiments.

As used herein, “a number of” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and a number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combination of these items can be present. In some illustrative examples, “at least one of” can be, for example, without limitation, two of item A; one of item B; and ten of item C; four of item B and seven of item C; or other suitable combinations.

In other illustrative examples, other number of simulators can be present in network data processing system 100 in addition to the three simulators shown. For example, 10, 50, 300, or some other number of simulators can be present and control client devices 110. Also, in some illustrative examples,

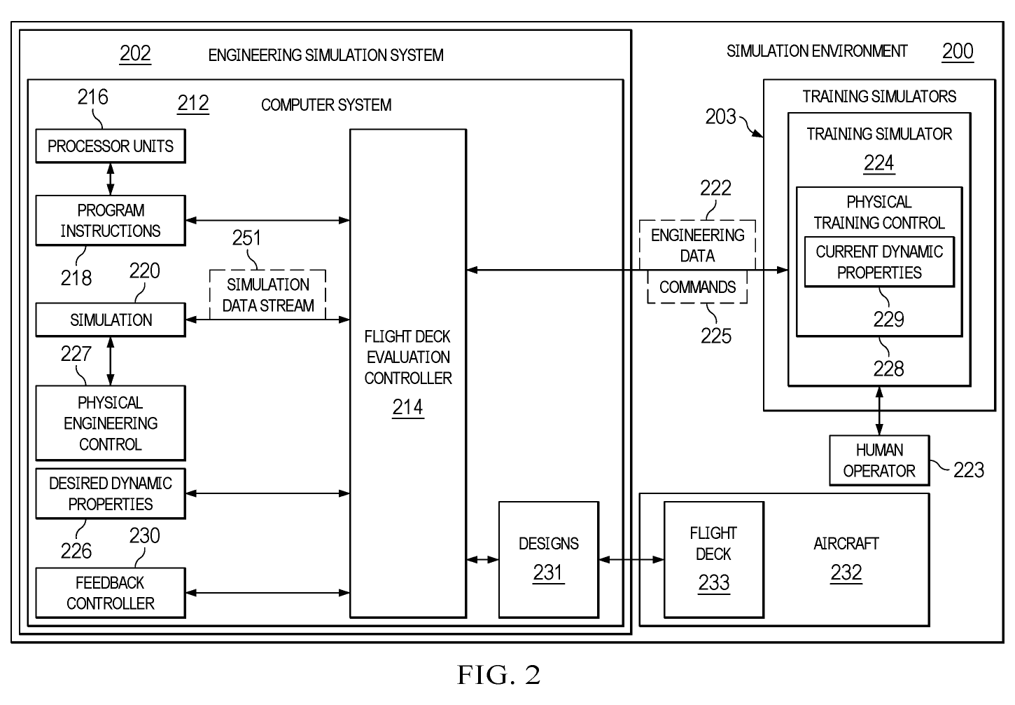

With reference now to FIG. 2, an illustration of a block diagram of a simulation environment is depicted in accordance with an illustrative embodiment. In this illustrative example, simulation environment 200 includes components that can be implemented in hardware such as the hardware shown in network data processing system 100 in FIG. 1.

Engineering simulation system 202 can run simulation 220 for a number of designs 231 for the flight deck 233 of aircraft 232. These designs can be for at least one of a physical control, a display system, a user interface, or other components for flight deck 233 of aircraft 232. In this example, aircraft 232 can be selected from a group comprising a commercial airplane, a cargo airplane, a tilt-rotor aircraft, a tilt wing aircraft, a vertical takeoff and landing aircraft, a rotorcraft, an unmanned aerial vehicle, a drone, an electric vertical takeoff and landing vehicle, a personal air vehicle, a glider, a spaceplane, a rocket, a reusable launch vehicle, and other types of vehicles that can fly in the atmosphere.

Designs 231 evaluated through simulation 220 using the training simulators 203 can include at least one of a physical control, a location for a physical control such as a switch, a user interface for displaying information, a user interface for a crew alerting system, or other equipment or interfaces.

For example, designs 231 using simulation 220 can include human factors (HF) evaluations in which pilot responses to information displayed on display systems such as an engine indication and crew alerting system, an electronic centralized aircraft monitor, a multifunction display, a primary flight display, a navigation display, and other display systems. A change the manner in which information is displayed on the systems can be presented and evaluated through engineering simulations. Further, as part of this evaluation, the response of physical controls also play an important factor in determining the responses in these human factors evaluations.

Engineering simulation system 202 can run simulation 220 on a number of training simulators 203 to obtain engineering data 222. Training simulators 203 can take a number of different forms. For example, training simulators 203 can be selected from at least one of a full flight simulator (FFS), a flight training device (FTD), or other type of simulator.

In this illustrative example, engineering simulation system 202 includes computer system 212 and flight deck evaluation controller 214. As depicted, flight deck evaluation controller 214 is located in computer system 212.

Flight deck evaluation controller 214 can be implemented in software, hardware, firmware or a combination thereof. When software is used, the operations performed by flight deck evaluation controller 214 can be implemented in program instructions configured to run on hardware, such as a processor unit. When firmware is used, the operations performed by flight deck evaluation controller 214 can be implemented in program instructions and data and stored in persistent memory to run on a processor unit. When hardware is employed, the hardware can include circuits that operate to perform the operations in flight deck evaluation controller 214.

In the illustrative examples, the hardware can take a form selected from at least one of a circuit system, an integrated circuit, an application-specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field-programmable logic array, a field-programmable gate array, and other suitable hardware devices. Additionally, the processes can be implemented in organic components integrated with inorganic components and can be comprised entirely of organic components excluding a human being. For example, the processes can be implemented as circuits in organic semiconductors.

Computer system 212 is a physical hardware system and includes one or more data processing systems. When more than one data processing system is present in computer system 212, those data processing systems are in communication with each other using a communications medium. The communications medium can be a network. The data processing systems can be selected from at least one of a computer, a server computer, a tablet computer, or some other suitable data processing system.

As depicted, computer system 212 includes a number of processor units 216 that are capable of executing program instructions 218 implementing processes in the illustrative examples. In other words, program instructions 218 are computer-readable program instructions.

As used herein, a processor unit in the number of processor units 216 is a hardware device and is comprised of hardware circuits such as those on an integrated circuit that respond to and process instructions and program code that operate a computer.

When the number of processor units 216 executes program instructions 218 for a process, the number of processor units 216 can be one or more processor units that are in the same computer or in different computers. In other words, the process can be distributed between processor units 216 on the same or different computers in computer system 212.

Further, the number of processor units 216 can be of the same type or different types of processor units. For example, the number of processor units 216 can be selected from at least one of a single core processor, a dual-core processor, a multi-processor core, a general-purpose central processing unit (CPU), a graphics processing unit (GPU), a digital signal processor (DSP), or some other type of processor unit.

In this illustrative example, flight deck evaluation controller 214 is configured to perform a number of different operations. For example, flight deck evaluation controller 214 runs simulation 220 to collect engineering data 222. In this example, simulation 220 is run within computer system 212 and is presented to human operator 223 through training simulator 224 in training simulators 203. Human operator 223 can be a pilot, copilot, a crew member, or other person.

In this example, simulation 220 outputs simulation data stream 251. This information includes information that is used to present simulation 220 on a simulator. For example, simulation data stream 251 can include control signals, stimulus data, motion cueing data, regular commands, simulated sensor data, as well as other types of data used to present simulation 220. Control signals can be commands for force feedback, resistance, actuator positions, and other commands for hardware in a simulator. Stimulus data can be visual, auditory, and haptic cues. Motion cueing data can control motion on platforms or haptic responses. Rendering commands can render video or present audio on hardware in the simulator. Simulated sensor data can simulate data that is presented on instruments or environmental sensors.

In this example, simulation data stream 251 is received by flight deck evaluation controller 214 and processed and sent to training simulator 224 for presentation on training simulator 224. Simulation data stream 251 as received from simulation 220 is simulator specific for an engineering simulator and the hardware in that type simulator as compared to the hardware in training simulator 224.

In this example, flight deck evaluation controller 214 processes this simulation data stream to make the simulation data stream 251 specific to the hardware in training simulator 224. For example, this processing is performed to cause physical controls in training simulator 224 to perform as close as possible to the actual physical control that these controls represent. This type of fidelity for physical controls is important in providing the as close as possible the same handling characteristics and responses as actual physical controls in an aircraft.

Further, even when engineering data 222 is collected for other designs that do not involve physical controls, a level of fidelity for the physical controls is provided that reduces or avoids distractions that can occur for pilots when controls do not perform as actual controls. The performance is how accurately and responsively the behavior of real aircraft controls used in simulation 220 are replicated using physical controls such as physical engineering control 227 and physical training control 228.

For example, distractions caused by a difference in the performance of physical controls can result in inaccurate collection of engineering data 222 for human factors scenarios in which designs 231 for information displayed on display systems. The inaccurate collection can occur because of distractions caused by the performance of physical controls that do not perform as close as possible to actual physical controls.

In this example, flight deck evaluation controller 214 identifies a number of desired dynamic properties 226 for physical engineering control 227 used in simulation 220 from simulation data stream 251. In this example, the number of desired dynamic properties 226 are a number of dynamic properties that may be different from the number of dynamic properties that are currently present for a physical engineering control 227.

Dynamic properties are the characteristics of a physical control that describe how the physical control responds to changes in a simulation or in response to user input. In this example, dynamic properties can be selected from at least one of a movement, a speed of the movement, a resistance to being moved by a human operator, a back drivability from external forces, a dampening, a vibration, a tactile feedback, a position, or other properties. These properties can change during simulation 220.

Flight deck evaluation controller 214 identifies physical training control 228 in training simulator 224 that is an equivalent of the physical engineering control 227. In this illustrative example, a physical control, such as physical training control 228 or physical engineering control 227 is a physical component that can be manipulated or controlled by human operator 223. The physical training control can be selected from a group comprising a physical control, a back driven control, an auto throttle, a speed brake, a wheel, a column, pedals, an inceptor, a side stick, thrust control levers, a trim control, a flap lever, and other types of physical controls.

In this example, physical training control 228 is considered the equivalent of physical engineering control 227 when physical training control 228 replicates the essential form, function, and response behavior necessary for its intended use, even if the underlying hardware, instrumentation, or control laws differ. In other words, two physical controls can be equivalent to each other even though the underlying components are not exactly the same. In this example, equivalence means that physical training control 228 can be used in simulation 220 with consistent pilot interaction, motion range, and control feel within the fidelity required for training even though this control does not support higher-resolution sensing and flexible dynamic tuning for test and development purposes as physical engineering control 227.

Flight deck evaluation controller 214 uses the number of desired dynamic properties 226 determined from simulation data stream 251 as the number of desired dynamic properties 226 for physical training control 228. Flight deck evaluation controller 214 sends commands 225 to physical training control 228 using a difference between the number of current dynamic properties 229 and the number of desired dynamic properties 226 and feedback controller 230.

In this example, feedback controller 230 is a control system or process that monitors a number of current dynamic properties 229 of physical training control 228 and compares them to the number of desired dynamic properties 226. The comparison results in a difference. This difference can take the form of an error. In one example, the error is a summation of the current error and a number of prior errors. Feedback controller 230 can be selected from at least one of a proportion-integral-derivative controller, a proportional controller, a neural network controller, or other suitable feedback control mechanism.

In one example, flight deck evaluation controller 214 uses feedback controller 230 to determine an error from the difference between the number of current dynamic properties 229 and the number of desired dynamic properties 226. Flight deck evaluation controller 214 selects a command to cause the number of current dynamic properties 229 to change towards the number of desired dynamic properties. Flight deck evaluation controller 214 sends the command to physical training control 228. These operations can be repeated until the amount of error is less than some threshold or some period of time has passed. In some examples, all of these operations can be performed by flight deck evaluation controller 214 using feedback controller 230.

In one example, physical training control 228 is a throttle. Further in this example, the number of desired dynamic properties 226 is a new position for the throttle based on the operation of an autopilot in simulation 220. This new position is identified in simulation data stream 251. In this example, the throttle has a position sensor that detects the position of the throttle.

In this example, flight deck evaluation controller 214 uses feedback controller 230 to perform operations to generate commands 225. Feedback controller 230 identifies the error between the current position and the desired position for throttle. In response to the error, feedback controller 230 generates a command such as a speed to move the throttle. This speed command can be sent to the throttle to move the throttle. A new measurement can be made for the position by feedback controller 230 as further feedback.

Additional speed commands can be sent to the throttle until the throttle reaches the desired position. The speed used to move the throttle can also be identified from simulation data stream 251.

Thus, the speed and position of the throttle can be moved in a manner that is the same as an actual physical throttle in a flight deck that is being simulated in simulation 220. This movement of the throttle occurs even though this throttle is not the same as an actual throttle that may be used in engineering simulation. However, the movement and positioning of this training throttle can be controlled to provide the same movement as an actual engineering throttle. For example, if commands 300 includes speed, flight deck evaluation controller 214 may apply scaling of the speed command to generate commands 225 for physical training control 228 to take into account differences between physical engineering control 227 and physical training control 228. Different simulators can have a different types of motors that are controlled differently. On some simulators the motor is controlled by commands to change the current. On other simulators, commands for speed can be used to control the motor. On yet other simulators, the motors are matched to those used in the actual aircraft and do not need changes to the commands from simulation 220.

Further, sending commands 225 to physical training control 228 can be performed using the error between the number of current dynamic properties and the number of desired dynamic properties, a safety check for the number of current dynamic properties, and the feedback controller 230. The safety check can be used to prevent movement of the physical control, such as a throttle, at the end of the movement range. The command to move the model further from the end is not made to avoid stressing or damaging the control. In another example, the movement of the control can be made such that it limits the force used for safety purposes.

Flight deck evaluation controller 214 collects the engineering data 222 from the training simulator 224 during simulation 220. Engineering data 222 is data generated from measurements and response characteristics generated by the hardware in training simulator 224 during the presentation of simulation 220. Engineering data 222 can be outputs or responses measured by physical components in training simulator 224, such as controls, actuators, displays, and other hardware during the presentation of simulation 220. For example, engineering data 222 can be received from physical pilot controls such as a throttle, a wheel, a column, and pedals.

In this example, engineering data 222 can include at least one of a video, an audio, flight dynamics data, control system data, propulsion data, human machine interface data, control input positions, actuator displacements, system response times, human operator data, and other types of data that can be measured from training simulator 224.

Flight dynamics data in engineering data 222 can include aircraft attitude, position, velocity, acceleration, and other flight parameters. This data can be used to determine the response to control inputs made by pilots during different flight conditions. This type of data can be used to validate and modify designs for aircraft systems.

Human operator data in engineering data 222 can include, for example, inputs generated by pilots manipulating controls in the simulator. This data can also include video and audio of pilots recorded by a camera system in training simulator 224. This type of data can provide information about pilot behaviors and reaction times. This data can be used to analyze ergonomics and workloads. Further, the data can be used to determine whether a particular aircraft design provides desired situational awareness of different scenarios and desired responses to those scenarios.

In one illustrative example, simulation 220 includes a number of changes to a configuration of flight deck 233. These number of changes can be at least one of a message change for a display, a different flight display device, different information on a current flight display device, a user interface change on the display, a change to the hardware controller, or other change to flight deck 233.

With this example, flight deck evaluation controller 214 analyzes engineering data 222 obtained from running simulation 220 on training simulator 224 to determine whether the number of changes meets a number of performance metrics. These metrics can include at least one of control input latency between a pilot input and system response, display readability for information displayed under different scenarios, error rates in human operator execution, layout effectiveness, and other metrics relating to the performance of changes to the configuration of flight deck 233.

In one illustrative example, one or more technical solutions are present that overcome a technical problem with collecting engineering data which a desired level of accuracy when presenting simulations on a training simulator instead of in engineering simulator. As a result, one or more technical solutions may provide a technical effect of providing an ability to present simulations on a training simulator in which the physical training controls can be controlled in a manner that provides greater fidelity, resulting in the collection of more accurate engineering data.

Computer system 212 can be configured to perform at least one of the steps, operations, or actions described in the different illustrative examples using software, hardware, firmware or a combination thereof. As a result, computer system 212 operates as a special purpose computer system in which flight deck evaluation controller 214 in computer system 212 enables collecting engineering data using training simulators.

In the illustrative example, the use of flight deck evaluation controller 214 in computer system 212 integrates processes into a practical application for collecting engineering data with an increased confidence in the level of accuracy for the engineering data. In this illustrative example, an engineering simulation system can send commands to a physical training control in a manner that provides a sufficient level of fidelity for the physical training control operated by human operator. In these examples, the fidelity in the performance of the physical training control is such that the human operator is not distracted by perceived differences between this training control and an actual physical control in the flight deck of an aircraft. By avoiding human operator perceiving differences, a distraction that can be created by this difference can be avoided resulting in more accurate responses of the human operator to scenarios being stimulated to collect the engineering data.

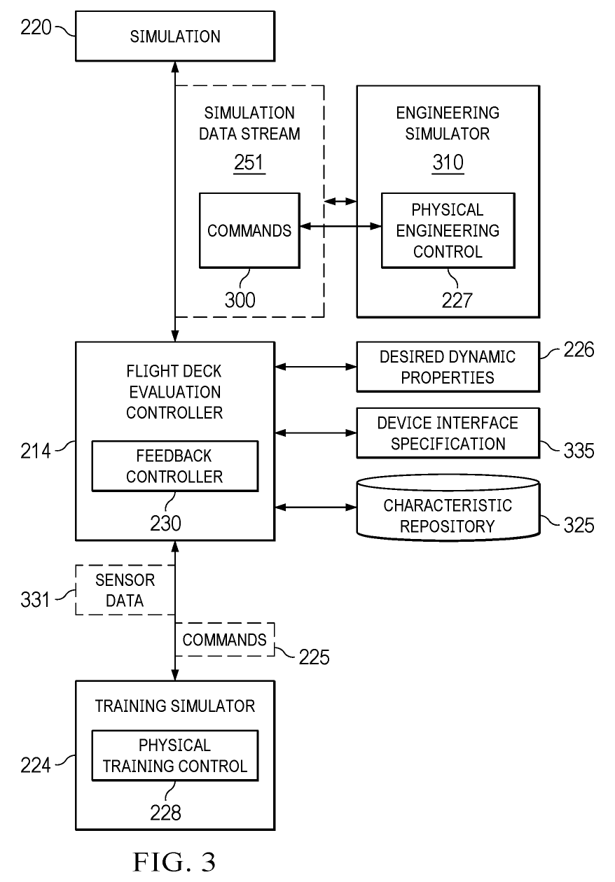

With reference to FIG. 3, an illustration of data flow used to control a training hardware controller is depicted in accordance with an illustrative embodiment. In the illustrative examples, the same reference numeral may be used in more than one figure. This reuse of a reference numeral in different figures represents the same element in the different figures.

As depicted, simulation 220 outputs simulation data stream 251 that is received by flight deck evaluation controller 214. This data stream is intended for presenting simulation 220 in engineering simulator 310. Flight deck evaluation controller 214 processes this simulation data stream in a manner that can be presented in training simulator 224.

In this example, simulation data stream 251 includes commands 300 used to control physical engineering control 227 in engineering simulator 310. These commands can be used to cause physical engineering control 227 to have a number of desired dynamic properties 226.

In this example, physical training control 228 in training simulator 224 is to be used instead of physical engineering control. Flight deck evaluation controller 214 identifies physical training control 228 in training simulator 224. In identifying physical training control 228, flight deck evaluation controller 214 determines device interface specification 335 for physical training control 228. This specification describes commands that physical training control 228 receives and data expected from this physical control. This information includes, for example, format, timing, signaling requirements, and other information needed to communicate with physical training control 228.

This specification can be determined ahead of time before running simulation 220 and provided flight deck evaluation controller 214. In this example, flight deck evaluation controller 214 can interrogate hardware and training simulator 224 to obtain device identifiers, model numbers, and other identifiers used to determine device interface specifications for the hardware in training simulator 224.

Further, all of the desired dynamic properties 226 for physical engineering control 227 may not be received in commands 300 in simulation data stream 251. For example, commands 300 include a position command for a control, which is a desired dynamic property. In moving to this position, physical engineering control 227 moves at least one of a force or speed. These properties are also desired dynamic properties 226 even though they are not specified in commands 300.

In this illustrative example, to maintain a desired level of fidelity in collecting engineering data, these other desired dynamic properties for the control are also identified. In this illustrative example, these desired dynamic properties can be identified using characteristic repository 325. This repository contains information about characteristics for different physical controls. Characteristics such as speed and force that physical engineering control 227 has when moving can be identified in this repository. These characteristics can be used as additional desired dynamic properties 226 in moving the control to the desired position in response to a position command in commands 300.

These desired dynamic properties identified for physical engineering control 227 are also used for physical training control 228. The specific commands to obtain the speed and force to match or emulate those for physical engineering control 227 can be generated by flight deck evaluation controller 214. In these examples, physical training control 228 can move with the speed or force in a manner that matches or emulates physical engineering control 227 because this control is considered to be an equivalent to physical engineering control 227.

With this identification, flight deck evaluation controller 214 generates commands 225 expected by physical training control 228. These commands can cause physical training control 228 to have desired dynamic properties 226. However, commands 300 used to obtain the number of desired dynamic properties 226 in physical engineering control 227 are different from commands 225 needed for physical training control 228 to reach desired dynamic properties 226.

In one illustrative example, physical engineering control 227 is an engineering automatic throttle and the command in commands 300 is to move the automatic throttle to a selected position. This engineering automatic throttle is an example of an actual automatic throttle used in aircraft. Commands 300 can be the same as sent to the actual automatic model in the aircraft for increased accuracy in presenting simulation 220 and receiving inputs from a human operator such as a pilot.

With this example, the number of desired dynamic properties 226 of this engineering automatic throttle is the commanded position. The number of desired dynamic properties 226 also includes the speed at which the engineering automatic throttle moves to the commanded position even though that speed is not one of commands 300. Thus, the positioning and the speed at which the engineering automatic throttle are the number of desired dynamic properties 226.

In this example, physical training control 228 is a training automatic throttle. The training automatic throttle is an equivalent to the automatic throttle and can be commanded to have desired dynamic properties 226. However, commands 300 used to obtain desired dynamic properties 226 in the automatic throttle are different from commands 225 needed for the training automatic throttle to reach desired dynamic properties 226.

For example, in addition to timing, format, and other protocol differences, the training automatic throttle does not operate using a position command. Instead, this physical training control is operated using a speed command.

This difference is more than merely translating one command from one format into another format. In this case, different commands are used by the engineering automatic throttle and the training automatic throttle. Thus, the processing of commands 300 for the engineering automatic throttle needed to obtain desired dynamic properties 226 for the training automatic throttle is more than merely a translation from one format for command to the format for the equivalent command. In this case, the commands are for performing different operations between the engineering automatic throttle and the training automatic throttle.

In this illustrative example, flight deck evaluation controller 214 generates commands 225 for physical training control 228 in the form of speed commands. In this example, this process of obtaining desired dynamic properties 226 for the training automatic throttle is more involved than merely converting a command such as position from one form into the same command in another form.

In this example, the speed command is generated and sent to physical training control 228. Further, sensor data 331 is received from physical training control 228 that indicates the position of the physical training control. This position information is used by feedback controller 230 to determine an error between the actual position and the desired position. This area is used to generate additional speed commands until the training automatic throttle has the desired dynamic property of the desired position.

Thus, in the illustrative example with the automatic throttle, a different type of command is used to control physical training control 228 as compared to the command used to control physical engineering control 227. As a result, controlling physical training control 228 to have desired dynamic properties 226 based on commands 300 is much more involved than merely translating a command from one format to another format.

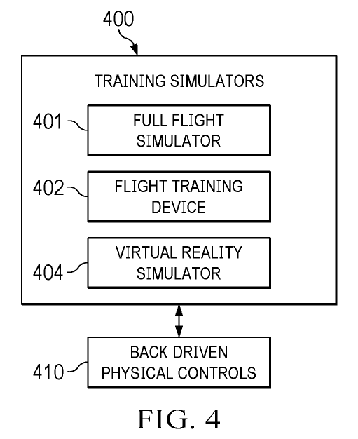

With reference to FIG. 4, an illustration of training simulators is depicted in accordance with an illustrative embodiment. In this illustrative example, training simulators 400 are an example of an implementation for training simulator 224 in FIGS. 2 and 3. In this example, training simulators 400 include full flight simulator 401, flight training device 402, virtual reality simulator 404, and virtual reality simulator 406.

In these illustrative examples, training simulators 400 include physical training controls in the form of back driven physical controls 410. Back driven physical controls 410 for training simulators 400 are control mechanisms that are actively moved for simulation to mimic the forces and movements that pilots feel in actual aircraft.

Full flight simulator 401 has flight controllers that provide bidirectional feedback. For example, the hardware for full flight simulator 401 is designed to replicate the hardware in the actual care plan for which the simulation is run. With this type simulator, force feedback, autopilot interaction, and other features are present. This type of simulator enhances training realism by ensuring control surfaces behave and feel as if they are in a real flight deck.

For example, when the airplane is in auto pilot in the simulation, the training controls can be back driven. The control wheel turns, the control column matches computer inputs, and the rudder pedals have deflections in this type of simulator. When in manual mode, the physical controls in the simulator for force applied to the pilot match those of the petals used in an airplane that is being simulated.

Flight training device 402 is a training simulator that has physical control devices. Other portions of this training simulator may take the form of touchscreen displays which display and enable user input to interact with switches, dials, and buttons that may be located in the flight deck. Some of these flight training devices may not have back driven physical control. Instead, some control may have motors and feedback devices which do not have the same level of performance as actual physical controls in a flight deck.

As another example, virtual reality simulator 404 is a training simulator in which much of the interaction with this training simulator is performed using a mouse, pointer, virtual reality headset, or other device. Computer graphics are used to render the flight deck components such as outstanding, overhead, mode control, and other components.

This virtual reality simulator can also have one or more back driven physical training controls. These controllers can be back driven and provide feedback.

With virtual reality simulator 406, back driven physical controls 410 take the form of at least one of a physical back driven control such as a yoke, stick, wheel, and other controls. Other back driven physical controls include a virtual reality (VR) headset, muscle stimulation system, a motion based hand controller with haptic cues, haptic gloves, or other types of devices that can provide performance desired to replicate the actual physical controls being simulated.

The use of back driven physical controls 410 enhances realism for purposes of collecting engineering data. These types of controllers simulate aerodynamic forces, trim changes, autopilot movements, or other movement features that act on back driven physical controls 410. This type of feedback is present even in actual controls for fly by wire systems.

The illustration of simulation environment 200 and the different components in FIG. 2-4 is not meant to imply physical or architectural limitations to the manner in which an illustrative embodiment may be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

For example, flight deck evaluation controller 214 can operate to present simulations to one or more of training simulators 203 in addition to training simulator 224. In yet other illustrative examples, computer system 212 can be integrated as part of training simulator 224. For example, if training simulator 224 is a full flight simulator containing a movement platform and other components, computer system 212 may be located within this training simulator.

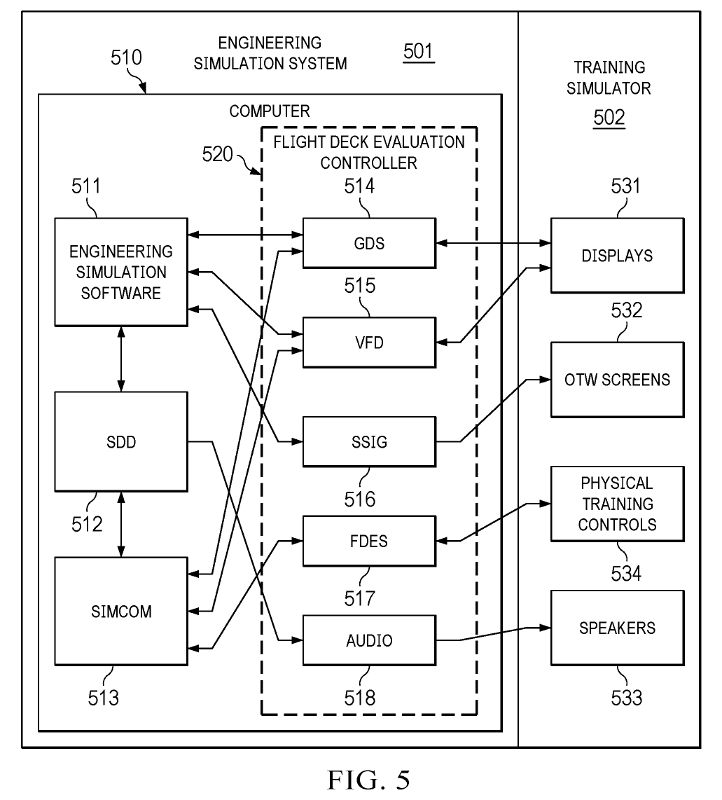

With reference next FIG. 5, an illustration of an engineering simulation system and a training simulator is depicted in accordance with an illustrative embodiment. As depicted, engineering simulation system 501 can operate to present a simulation on training simulator 502. Engineering simulation system 501 is an example of an implementation for engineering simulation system 202 in FIG. 2. Training simulator 502 is an example of an implementation for training simulator 224 FIG. 2.

Engineering simulation system 501 comprises computer 510 with software components that communicate with training simulator 502 to present a simulation. These components also collect engineering data.

Engineering simulation software 511 is software that is executed to run a simulation. In this example the software executes a simulation that is designed to be presented on an engineering training simulator.

In this example, simulation data dispatcher (SDD) 512 is an interface for engineering simulation software 511. SDD 512 operates to distribute, route, and synchronize data with different components. Simcom 513 is an interface and data exchange mechanism for different components in a simulation environment. In this example, SDD 512 and simcom 513 provide an interface to flight deck evaluation controller (FDES) 517. In these examples, SDD 512 shares data with the simulation being run by engineering simulation software 511. Some applications, such as audio 518, communicate directly with SDD 512 because those components can directly use data in the simulation data stream generated by engineering simulation software 511. Other applications are unable to directly use the data and commands in the simulation registration. In this case, Simcom 513 provides an interface to translate or convert information and commands in the simulation data stream into a form usable by these components. ]

For example, SDD 512 provides an interface to audio 518 and simcom 513. Simcom 513 provides an interface to graphics display system (GDS) 514, virtual flight deck (VFD) 515, and FDES 517.

As depicted, GDS 514 operates to provide simulated displays. For example, GDS 514 can display control and alerting functions and other information that is displayed on displays 531. These displays can include, for example, a primary flight display, a navigation display, and other types of displays. GDS 514 can control the displayed information received from engineering simulation software 511. Further, these displays can be touch screen displays and receive user input.

In this example, VFD 515 provides simulator control panels that are presented on displays 531 that are touch screen displays. VFD 515 can receive user input that is sent back to engineering simulation software 511. Further, this input can also be collected as engineering data. SSIG 516 renders what is seen outside of the flight deck windows on outside the window (OTW) screens 532. Audio 518 presents sounds and aurals for the simulation on speakers 533.

FDES 517 controls physical training controls 534. In this example, FDES 517 provides a translation of commands for physical engineering controls from engineering simulation software 511 into a form for physical training controls 534 to replicate desired dynamic properties for physical training controls 534. Further, FDES 517 can receive user input to physical training controls 534 and data generated by physical training controls 534 and send this information back to engineering simulation software 511. Further, some of this information is also collected as engineering data.

The illustration of engineering simulation system 501 and training simulator 502 in FIG. 5 is provided as an example of engineering simulation system 202 and training simulator 502 in FIG. 2 and is not meant to limit the manner in which other illustrative examples can be implemented. For example, training simulator 502 can also include a camera system. The systems can be one or more cameras that can record information about pilot interactions with training simulator 502. This information can also be collected as engineering data for analysis.

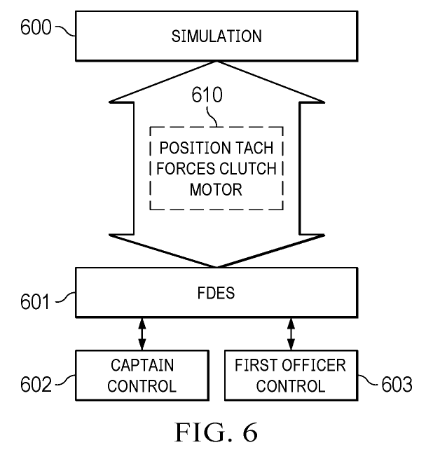

Turning to FIG. 6, an illustration of a dataflow for controlling physical training controls is depicted in accordance with an illustrative embodiment. In this illustrative example, simulation 600 is an example of simulation 220 in FIG. 2 and flight deck evaluation controller (FDES) 601 is an example of flight deck evaluation controller (FDES) 517. Captain control 602 and first officer control 603 are an example of physical training control 228 in FIG. 2.

In this illustrative example, simulation 600 communicates information 610 with flight deck evaluation controller (FDES) 601 to change the position of training controls in the form of captain control 602 and first officer control 603 during simulation 600. These back driven controls can be flight controls such as a wheel, a column, and pedals. These controls can be moved by FDES 601 using motors and actuators in these controls in a manner that matches fly by wire airplane controls of an actual aircraft.

The outputs in information 610 from simulation 600 are mapped by FDES 601 to provide as close to accurate behavior as these controls in actual flight. In this example, the input and output in information 610 can include position, tack, forces, and clutch motor commands.

Position can be the desired and actual position of the back drive controls. Tach is the rate at which the motors are turning, and forces are the simulated forces that the control load should exert on a human operator for dynamics and feel. In this depicted example, clutch motor movement is the movement of a motor used to move the back driven controls during auto flight.

In this example, inputs and outputs in information 610 are mapped and modified by FDES 601 for simulation 600 and the back drive controls. For example, FDES 601 coverts engineering units that need to be converted. In this example, the engineering units are the units of measure such as knots, degrees, feet, feet per second, nautical miles, and other units. These data and commands can be converted for communicating with physical training controls 534.

In these examples, captain control 602 and first officer control 603 can move very quickly. If the aircraft in simulation 600 were to hit a mountain, for example, when captain control 602 and first officer control 603 are control columns, the abrupt stopping of the airplane drives these controls forward rapidly and could injure a user. In these examples, FDES 601 implements safety checks and limits to prevent excessive movement of the control column.

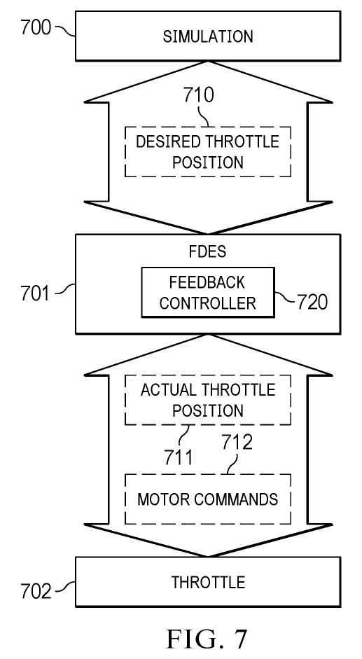

Turning to FIG. 7, an illustration of a dataflow for controlling a throttle is depicted in accordance with an illustrative embodiment. In this illustrative example, simulation 600 is an example of simulation 220 in FIG. 2 and flight deck evaluation controller (FDES) 701 is an example of flight deck evaluation controller (FDES) 517. Throttle 702 is an example of physical training control 228 in FIG. 2.

In this example, simulation 700 outputs desired throttle position 710 to FDES 701 in desired throttle position for a throttle in simulation 700. In this example, the movement and motor input of throttle 702 are incompatible with desired throttle position 710 commanded through simulation 700. In this example, moving the throttle quickly without overshooting a desired throttle position, is used to increase the accuracy of engineering data collected from simulation 700. This realism reduces or eliminates the distraction that pilot may have from throttle does feel or move like an actual throttle in an aircraft that is being simulated in simulation 700.

However, it is desirable to have throttle 702 move for pilot awareness and effect. For example, pilots usually keep their hands on the throttle, even in auto throttle mode, for awareness and being ready to take over.

If a pilot needs to take over control in a given scenario, the throttle should already be in the correct position to avoid odd throttle input and undesired distractions. The fidelity in the positioning and movement of throttle 702 is useful in obtaining accurate engineering data in scenarios in which pilots may operate throttle 702 or view information on displays. Inaccuracy in the movement or positioning of throttle 702, as compared to an actual throttle in an aircraft, can distract the pilots in a manner that prevents the pilot from performing actions accurately in simulation 700.

FDES 701 receives actual throttle position 711 from throttle 702. This position information can be generated using sensors that detect the position of throttle 702. The sensors can be, for example, an optical encoder, a linear potentiometer, and other types of sensors.

In response to actual throttle position 711, FDES 701 uses feedback controller 720 to generate and send motor commands 712 to throttle 702. Motor commands 712 can be, for example, amps, speed, tach, or other commands to operate the motor that moves throttle 702. In this example, feedback controller 720 can determine the difference between desired throttle position 710 and actual throttle position 711. This error can be used to generate additional commands until actual throttle position 711 reaches or is within a preferable tolerance design from desired throttle position 710.

In these examples, calculating the amount of time at a selected current amplitude (amp) for throttle 702 to move from actual throttle position 711 to desired throttle position 710 and applying that current amplitude for that period of time may not provide the desirable outcome. For example, the motor in throttle 702 may not have the same speed of movement for a given current amplitude throughout entire management positions of throttle 702.

In another illustrative example, simulation 700 also outputs speed for the throttle to move to desired throttle position 710. With this additional parameter, FDES 701 can use feedback controller 720 to calculate how fast or slow to move throttle 702 to reach the desired throttle position.

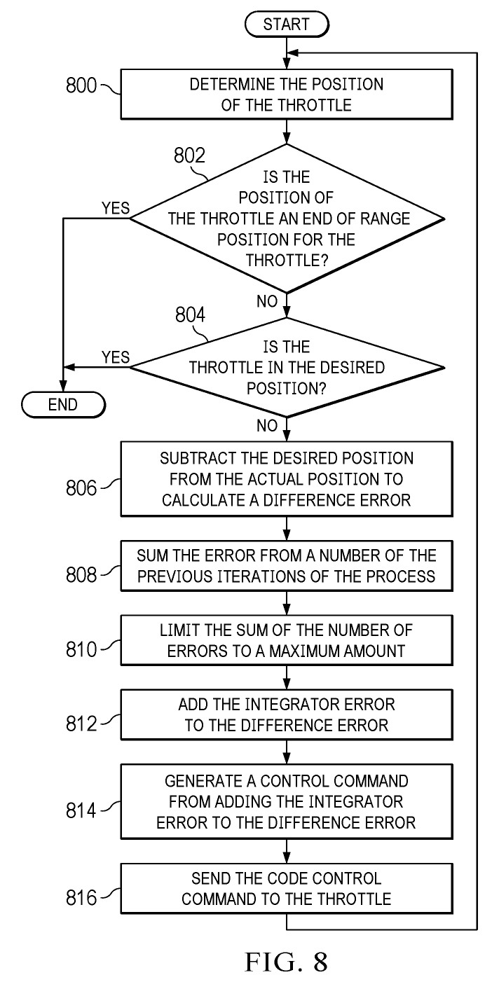

With reference to FIG. 8, an illustration of a flowchart of a process for controlling movement of a throttle is depicted in accordance with an illustrative embodiment. The process in this figure can be implemented in flight deck evaluation controller (FDES) 701 to control throttle 702.

The process begins by determining the position of the throttle (operation 800). This position can be determined from sensor data received from the throttle. A determination is made as to whether the position of the throttle is at an end of range position for the throttle (operation 802). Operation 802 is used to ensure that the motor does not burn out if the throttle is already all the way forward or all the way back.

In operation 802, if the throttle is at an end of range position, the process terminates. Otherwise, the process determines whether the throttle is in the desired position (operation 804). If the throttle is in the desired position, the process terminates.

Otherwise, the process subtracts the desired position from the actual position to calculate an error difference (operation 806).

The process sums the error from a number of the previous iterations of the process (operation 808). In this operation, the error can be referred to as an integration error that is a summation of the current error and a number of prior errors. This error is also referred to as an integrated error or a cumulative error.

The process limits the sum of the number of errors to a maximum amount (operation 810). In operation 810, limiting the sum of the number of errors to some maximum amount can control smoothness in the movement of the throttle.

The process adds the integrator error to the difference error (operation 812). The process generates a control command from adding the integrator error to the difference error (operation 814). In this example, the control command is a command to the motor such as amplitude, speed, or other command used by the motor in the throttle.

The process sends the code control command to the throttle (operation 816). The process then returns to operation 800 as described above.

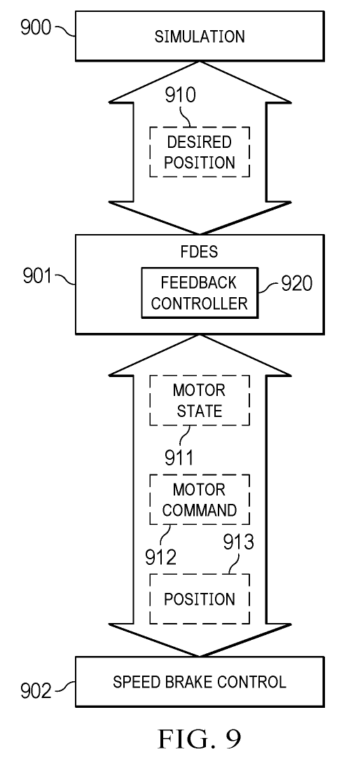

Next in FIG. 9, an illustration of a dataflow for controlling a speed brake control is depicted in accordance with an illustrative embodiment. In this illustrative example, simulation 900 is an example of simulation 220 in FIG. 2 and flight deck evaluation controller (FDES) 901 is an example of flight deck evaluation controller (FDES) 517. Speed brake control 902 is an example of physical training control 228 in FIG. 2.

In this illustrative example, speed brake control 902 is a physical control that operates a speed brake having an auto deploy and stow feature. For example, if the speed brake is deployed and the pilot aborts a landing by advancing the throttles, the speed brake automatically stows. If the pilot forgets to extend the speed brake and engages reverse thrust, the speed brake automatically extends.

In this example, simulation 900 sends desired position 910 to FDES 901. In this example, speed brake control 902 has two positions, deployed and stowed. These positions are controlled by solenoid which also has a lock to maintain the position of the solenoid. Speed brake control 902 has two electrical components that are controlled for the simulation. One component is a motor and the other is a solenoid.

The motor is single speed that can be controlled to be on, off, and a direction. If an error is calculated, the motor runs until a stop is reached.

The solenoid is a semi-locking mechanism that enables the pilot to move the lever to the Armed position without having to look at speed brake control 902. The solenoid provides a momentary stop to prevent the speed brake from accidentally being extend in the wrong phase of flight. The pilot can override the solenoid at any time. The function of FDES 901 is to translate the state of the speed brake control 902 to match that in simulation 900.

If motor state of the solenoid is false, speed brake control 902 is in a locked or armed position such as a detent in the range of movement for speed brake control 902. If the command for desired position 910 from simulation 900 is for the speed brake to extend, FDES 901 uses feedback controller 920 to generate motor command 912 to move speed brake control 902 into a deployed position. In this example, motor commands 712 can be bits that control solenoid for speed brake control 902. Position 913 can be received from speed brake control 902 in this example. This position can be a bit that indicated that the control is in a stowed position or a deployed position.

In this example, the error used by a feedback controller determines a position of the speed brake control 902. For example, with a speed brake control 902, this control in the flight deck can be in one of two positions, stowed and deployed. The desired dynamic property can be deployed and the actual dynamic property can be stowed. The error would be present if the speed control does not move from stowed to deployed in response to motor command 912 being sent to move the control.

Illustration of physical training controls in FIGS. 7 and 9 are provided as an example of some controls that can be used to implement physical training control 228 in FIG. 2 and is not meant to limit the manner in which other illustrative examples can be implemented. In other illustrative examples, other types of physical controls can be used such as a column, a wheel, or other suitable control.

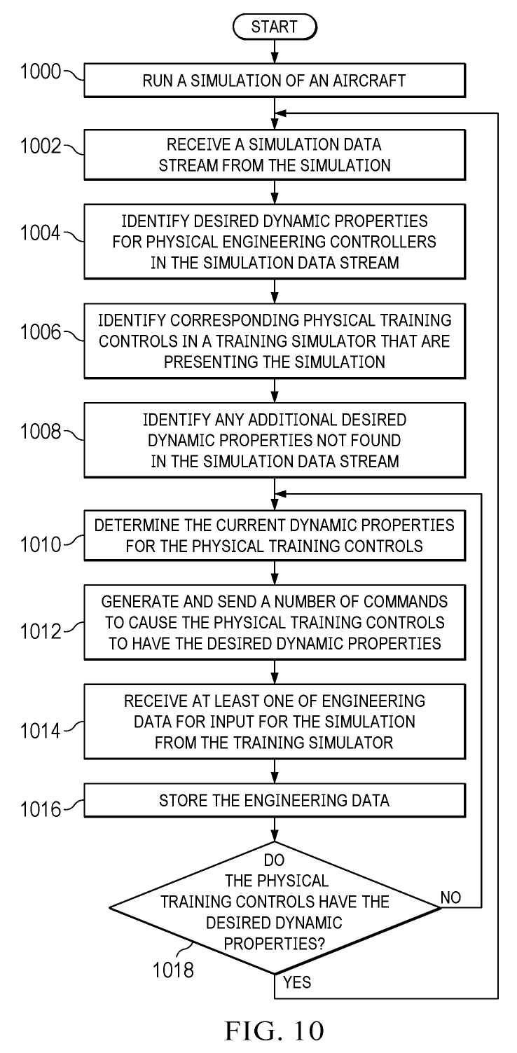

With reference to FIG. 10, an illustration of a flowchart of a process for collecting engineering data is depicted in accordance with an illustrative embodiment. The process in FIG. 10 can be implemented in hardware, software, or both. When implemented in software, the process can take the form of program instructions that are run by one of more processor units located in one or more hardware devices in one or more computer systems. For example, the process can be implemented in flight deck evaluation controller 214 in computer system 212 in FIG. 2.

The process begins by running a simulation of an aircraft (operation 1000). The process receives a simulation data stream from the simulation (operation 1002). The process identifies desired dynamic properties for physical engineering controllers in the simulation data stream (operation 1004). The process identifies corresponding physical training controls in a training simulator that are presenting the simulation (operation 1006).

The process identifies any additional desired dynamic properties not found in the simulation data stream (operation 1008). For example, the simulation data stream may include a command to an auto throttle to move to a particular position as a desired dynamic property. Other desired dynamic properties not present in the simulation data stream include the speed at which the auto throttle is to move to the position. This identification can be made using a characteristic repository such as characteristic repository 325 in FIG. 3.

The process determines the current dynamic properties for the physical training controls (operation 1010). In this example, with the auto throttle, the current physical property is the position of the auto throttle.

The process generates and sends a number of commands to cause the physical training controls to have the desired dynamic properties (operation 1012). In this example, the auto throttle in the training simulator does not respond to commands in the form position. Instead, this physical training control responds to commands in the form of speed. Thus, the process generates a speed command for the auto throttle in place of the position command. The process uses a feedback controller to move the auto throttle with the speed command to the desired position. Further, this process can determine as a characteristic of the auto throttle in the engineering simulator such that the auto throttle in the training simulator moves at the same speed as the auto throttle in the engineering simulator. In this example, operations 1006 can be iterative operation in which the feedback controller receives position data about the auto throttle and generates speed commands based on the error determined between the current position in the desired position for the auto throttle.

The process receives at least one of engineering data for input for the simulation from the training simulator (operation 1014). The process stores the engineering data (operation 1016).

The process determines whether the physical training controls have the desired dynamic properties (operation 1018). If the training controls do not have the desired dynamic properties, the process returns to operation 1010. Otherwise, the process returns to operation 1002.

In this manner, increased fidelity in presenting the simulation is present enabling collection of engineering data in a more accurate manner. The operations depicted in this flowchart are only examples of some of the operations performed to collect engineering data. Other operations are present but not shown for purposes of illustrating the collection of engineering data. For example, operations are present to receive user input from the pilot in the training simulator and send that input back to the simulation for processing.

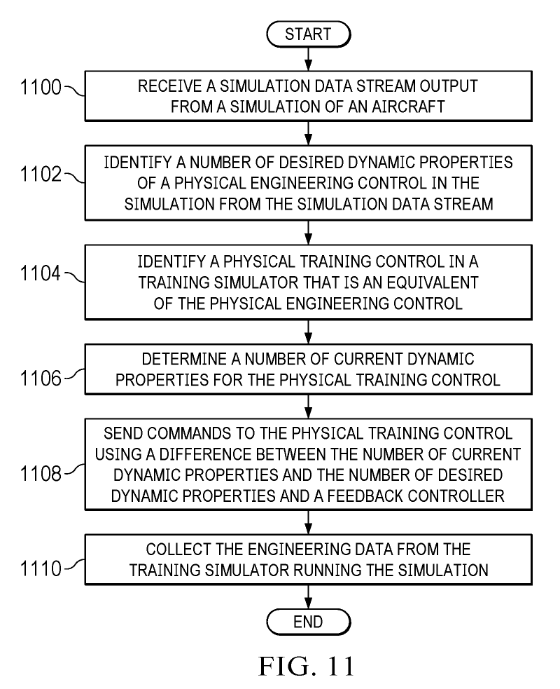

Turning next to FIG. 11, an illustration of a flowchart of a process for collecting engineering data is depicted in accordance with an illustrative embodiment. The process in FIG. 11 can be implemented in hardware, software, or both. When implemented in software, the process can take the form of program instructions that are run by one of more processor units located in one or more hardware devices in one or more computer systems. For example, the process can be implemented in flight deck evaluation controller 214 in computer system 212 in FIG. 2.

The process begins by receiving a simulation data stream output from a simulation of an aircraft (operation 1100). This simulation can be run by flight deck evaluation controller 214 or by another component in communication with flight deck evaluation controller 214 in FIG. 2.

The process identifies a number of desired dynamic properties of a physical engineering control in the simulation from the simulation data stream (operation 1102). The process identifies a physical training control in a training simulator that is an equivalent of the physical engineering control (operation 1104).

The process determines a number of current dynamic properties for the physical training control (operation 1106). The process sends commands to the physical training control using a difference between the number of current dynamic properties and the number of desired dynamic properties and a feedback controller (operation 1108).

The process collects the engineering data from the training simulator running the simulation (operation 1110). The process terminates thereafter.

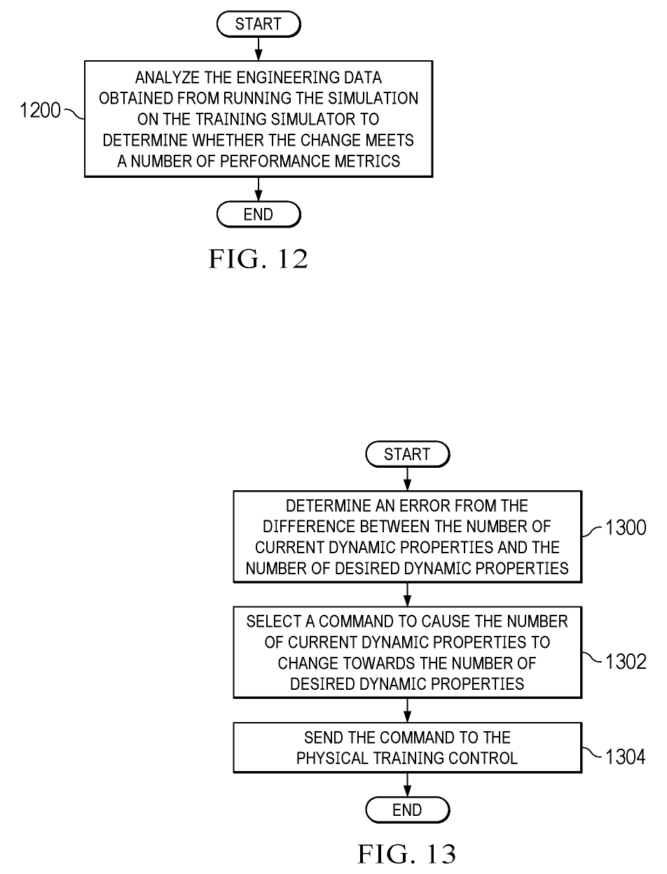

Turning next to FIG. 12, an illustration of a flowchart of a process for analyzing engineering data is depicted in accordance with an illustrative embodiment. The process in this flowchart is an example of an additional operation that can be performed with the operations in FIG. 11. In FIG. 12, a number of changes to the configuration of the flight deck are present in the simulation. The number of changes is selected from at least one of a message change on a display; a different flight display device; different information on a current flight display device; a user interface change on the display; a change to a hardware controller; or other changes to the flight deck.

The process analyzes the engineering data obtained from running the simulation on the training simulator to determine whether the change meets a number of performance metrics (operation 1200). The process terminates thereafter.

With reference to FIG. 13, an illustration of a flowchart of a process for sending commands to a simulator is depicted in accordance with an illustrative embodiment. The process in this flowchart is an example of an implementation for operation 1108 in FIG. 11.

The process determines an error from the difference between the number of current dynamic properties and the number of desired dynamic properties (operation 1300). In operation 1300, the error can be a summation of the current error and a number of prior errors. This type of error is also referred to as an integrated error or a cumulative error.

The process selects a command to cause the number of current dynamic properties to change towards the number of desired dynamic properties (operation 1302). The process sends the command to the physical training control (operation 1304). The process terminates thereafter.

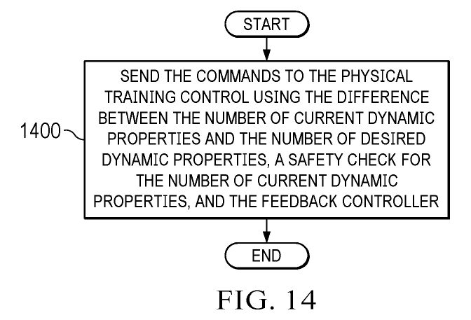

In FIG. 14, an illustration of a flowchart of a process for sending commands is depicted in accordance with an illustrative embodiment. The process in this flowchart is an example of an implementation for operation 1108 in FIG. 11.

The process sends the commands to the physical training control using the difference between the number of current dynamic properties and the number of desired dynamic properties, a safety check for the number of current dynamic properties, and the feedback controller (operation 1400). The process terminates thereafter.

The flowcharts and block diagrams in the different depicted embodiments illustrate the architecture, functionality, and operation of some possible implementations of apparatuses and methods in an illustrative embodiment. In this regard, each block in the flowcharts or block diagrams can represent at least one of a module, a segment, a function, or a portion of an operation or step. For example, one or more of the blocks can be implemented as program instructions, hardware, or a combination of the program instructions and hardware. When implemented in hardware, the hardware can, for example, take the form of integrated circuits that are manufactured or configured to perform one or more operations in the flowcharts or block diagrams. When implemented as a combination of program instructions and hardware, the implementation may take the form of firmware. Each block in the flowcharts or the block diagrams can be implemented using special purpose hardware systems that perform the different operations or combinations of special purpose hardware and program instructions run by the special purpose hardware.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

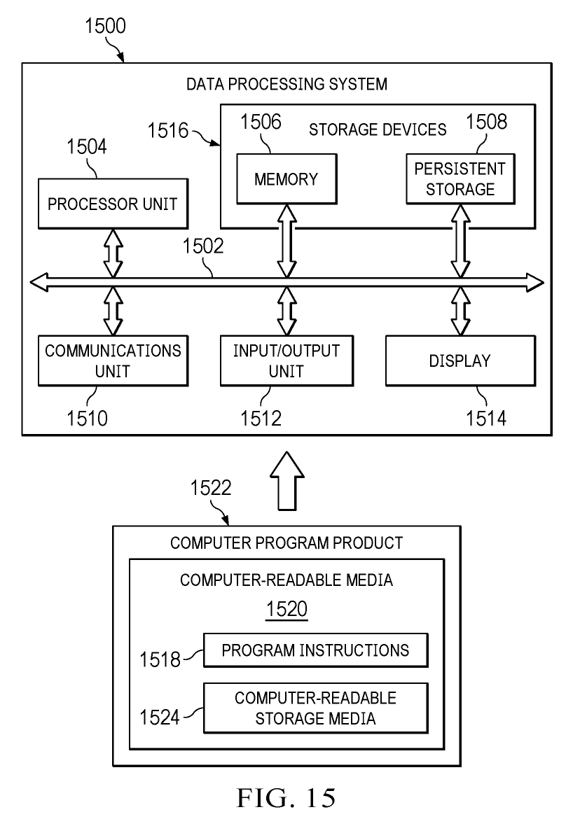

Turning now to FIG. 15, an illustration of a block diagram of a data processing system is depicted in accordance with an illustrative embodiment. Data processing system 1500 can be used to implement server computer 104, server computer 106, client devices 110, in FIG. 1. Data processing system 1500 can also be used to implement [ADD COMPUTING SYSTEMS IN PRIOR FIGURES HERE]. In this illustrative example, data processing system 1500 includes communications framework 1502, which provides communications between processor unit 1504, memory 1506, persistent storage 1508, communications unit 1510, input/output (I/O) unit 1512, and display 1514. In this example, communications framework 1502 takes the form of a bus system.

Processor unit 1504 serves to execute instructions for software that can be loaded into memory 1506. Processor unit 1504 includes one or more processors. For example, processor unit 1504 can be selected from at least one of a multicore processor, a central processing unit (CPU), a graphics processing unit (GPU), a physics processing unit (PPU), a digital signal processor (DSP), a network processor, or some other suitable type of processor. Further, processor unit 1504 can be implemented using one or more heterogeneous processor systems in which a main processor is present with secondary processors on a single chip. As another illustrative example, processor unit 1504 can be a symmetric multi-processor system containing multiple processors of the same type on a single chip.

Memory 1506 and persistent storage 1508 are examples of storage devices 1516. A storage device is any piece of hardware that is capable of storing information, such as, for example, without limitation, at least one of data, program instructions in functional form, or other suitable information either on a temporary basis, a permanent basis, or both on a temporary basis and a permanent basis. Storage devices 1516 may also be referred to as computer-readable storage devices in these illustrative examples. Memory 1506, in these examples, can be, for example, a random-access memory or any other suitable volatile or non-volatile storage device. Persistent storage 1508 may take various forms, depending on the particular implementation.

For example, persistent storage 1508 may contain one or more components or devices. For example, persistent storage 1508 can be a hard drive, a solid-state drive (SSD), a flash memory, a rewritable optical disk, a rewritable magnetic tape, or some combination of the above. The media used by persistent storage 1508 also can be removable. For example, a removable hard drive can be used for persistent storage 1508.

Communications unit 1510, in these illustrative examples, provides for communications with other data processing systems or devices. In these illustrative examples, communications unit 1510 is a network interface card.

Input/output unit 1512 allows for input and output of data with other devices that can be connected to data processing system 1500. For example, input/output unit 1512 may provide a connection for user input through at least one of a keyboard, a mouse, or some other suitable input device. Further, input/output unit 1512 may send output to a printer. Display 1514 provides a mechanism to display information to a user.

Instructions for at least one of the operating system, applications, or programs can be located in storage devices 1516, which are in communication with processor unit 1504 through communications framework 1502. The processes of the different embodiments can be performed by processor unit 1504 using computer-implemented instructions, which may be located in a memory, such as memory 1506.

These instructions are referred to as program instructions, computer usable program instructions, or computer-readable program instructions that can be read and executed by a processor in processor unit 1504. The program instructions in the different embodiments can be embodied on different physical or computer-readable storage media, such as memory 1506 or persistent storage 1508.

Program instructions 1518 are located in a functional form on computer-readable media 1520 that is selectively removable and can be loaded onto or transferred to data processing system 1500 for execution by processor unit 1504. Program instructions 1518 and computer-readable media 1520 form computer program product 1522 in these illustrative examples. In the illustrative example, computer-readable media 1520 is computer-readable storage media 1524.

Computer-readable storage media 1524 is a physical or tangible storage device used to store program instructions 1518 rather than a medium that propagates or transmits program instructions 1518. Computer-readable storage media 1524 may be at least one of an electronic storage medium, a magnetic storage medium, an optical storage medium, an electromagnetic storage medium, a semiconductor storage medium, a mechanical storage medium, or other physical storage medium. Some known types of storage devices that include these mediums include: a diskette, a hard disk, a random access memory (RAM), a read-only memory (ROM), an erasable programmable read-only memory (EPROM or Flash memory), a static random access memory (SRAM), a compact disc read-only memory (CD-ROM), a digital versatile disk (DVD), a memory stick, a floppy disk, a mechanically encoded device, such as punch cards or pits / lands formed in a major surface of a disc, or any suitable combination thereof.

Computer-readable storage media 1524, as that term is used in the present disclosure, is not to be construed as storage in the form of transitory signals per se, such as at least one of radio waves or other freely propagating electromagnetic waves, electromagnetic waves propagating through a waveguide, light pulses passing through a fiber optic cable, electrical signals communicated through a wire, or other transmission media.

Further, data can be moved at some occasional points in time during normal operations of a storage device. These normal operations include access, de-fragmentation or garbage collection. However, these operations do not render the storage device as transitory because the data is not transitory while the data is stored in the storage device.

Alternatively, program instructions 1518 can be transferred to data processing system 1500 using a computer-readable signal media. The computer-readable signal media are signals and can be, for example, a propagated data signal containing program instructions 1518. For example, the computer-readable signal media can be at least one of an electromagnetic signal, an optical signal, or any other suitable type of signal. These signals can be transmitted over connections, such as wireless connections, optical fiber cable, coaxial cable, a wire, or any other suitable type of connection.

Further, as used herein, “computer-readable media 1520” can be singular or plural. For example, program instructions 1518 can be located in computer-readable media 1520 in the form of a single storage device or system. In another example, program instructions 1518 can be located in computer-readable media 1520 that is distributed in multiple data processing systems. In other words, some instructions in program instructions 1518 can be located in one data processing system while other instructions in program instructions 1518 can be located in one data processing system. For example, a portion of program instructions 1518 can be located in computer-readable media 1520 in a server computer while another portion of program instructions 1518 can be located in computer-readable media 1520 located in a set of client computers.

The different components illustrated for data processing system 1500 are not meant to provide architectural limitations to the manner in which different embodiments can be implemented. In some illustrative examples, one or more of the components may be incorporated in or otherwise form a portion of, another component. For example, memory 1506, or portions thereof, may be incorporated in processor unit 1504 in some illustrative examples. The different illustrative embodiments can be implemented in a data processing system including components in addition to or in place of those illustrated for data processing system 1500. Other components shown in FIG. 15 can be varied from the illustrative examples shown. The different embodiments can be implemented using any hardware device or system capable of running program instructions 1518.

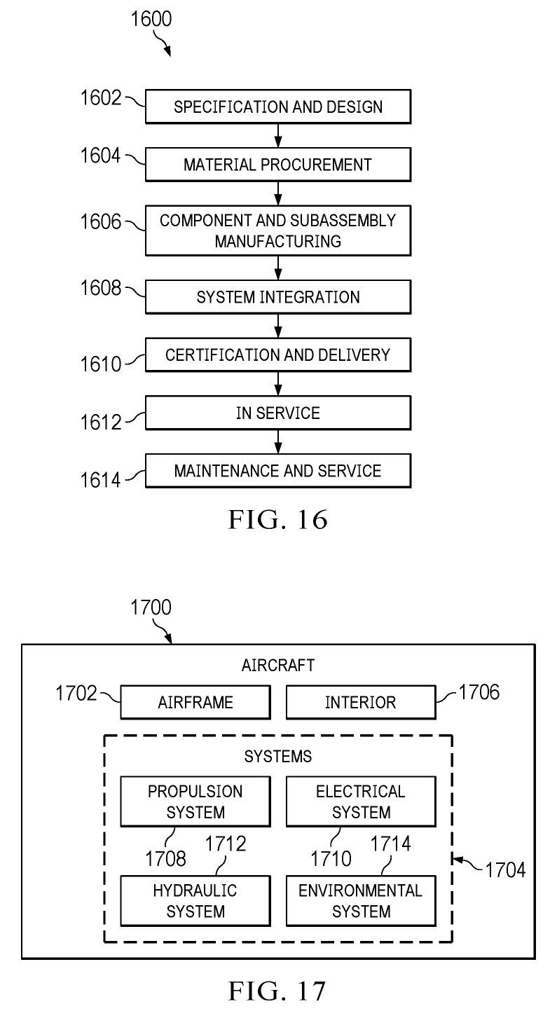

Illustrative embodiments of the disclosure may be described in the context of aircraft manufacturing and service method 1600 as shown in FIG. 16 and aircraft 1700 as shown in FIG. 17. Turning first to FIG. 16, an illustration of a block diagram of an aircraft manufacturing and service method is depicted in accordance with an illustrative embodiment. During pre-production, aircraft manufacturing and service method 1600 may include specification and design 1602 of aircraft 1700 in FIG. 17 and material procurement 1604.

During production, component and subassembly manufacturing 1606 and system integration 1608 of aircraft 1700 in FIG. 17 takes place. Thereafter, aircraft 1700 in FIG. 17 can go through certification and delivery 1610 in order to be placed in service 1612. While in service 1612 by a customer, aircraft 1700 in FIG. 17 is scheduled for routine maintenance and service 1614, which may include modification, reconfiguration, refurbishment, and other maintenance or service.

Each of the processes of aircraft manufacturing and service method 1600 may be performed or carried out by a system integrator, a third party, an operator, or some combination thereof. In these examples, the operator may be a customer. For the purposes of this description, a system integrator may include, without limitation, any number of aircraft manufacturers and major-system subcontractors; a third party may include, without limitation, any number of vendors, subcontractors, and suppliers; and an operator may be an airline, a leasing company, a military entity, a service organization, and so on.

With reference now to FIG. 17, an illustration of a block diagram of an aircraft is depicted in which an illustrative embodiment may be implemented. In this example, aircraft 1700 is produced by aircraft manufacturing and service method 1600 in FIG. 16 and may include airframe 1702 with plurality of systems 1704 and interior 1706. Examples of systems 1704 include one or more of propulsion system 1708, electrical system 1710, hydraulic system 1712, and environmental system 17 14. Any number of other systems may be included. Although an aerospace example is shown, different illustrative embodiments may be applied to other industries, such as the automotive industry.

Apparatuses and methods embodied herein may be employed during at least one of the stages of aircraft manufacturing and service method 1600 in FIG. 16.

In one illustrative example, components or subassemblies produced in component and subassembly manufacturing 1606 in FIG. 16 can be fabricated or manufactured in a manner similar to components or subassemblies produced while aircraft 1700 is in service 1612 in FIG. 16. As yet another example, one or more apparatus embodiments, method embodiments, or a combination thereof can be utilized during production stages, such as component and subassembly manufacturing 1606 and system integration 1608 in FIG. 16. One or more apparatus embodiments, method embodiments, or a combination thereof may be utilized while aircraft 1700 is in service 1612, during maintenance and service 1614 in FIG. 16, or both. The use of a number of the different illustrative embodiments may substantially expedite the assembly of aircraft 1700, reduce the cost of aircraft 1700, or both expedite the assembly of aircraft 1700 and reduce the cost of aircraft 1700.

For example, engineering simulation system 202 in FIG. 2 can be used during specification and design 1602 or maintenance and service 1614. Simulations can be run using engineering simulation system 202 with training simulators 203 in FIG. 2 to collect engineering data from larger numbers of pilots as compared to current techniques for use in evaluating designs for new aircraft.

Further, engineering simulation system 202 in FIG. 2 can be used as part of maintenance and service 1614 to collect engineering data to evaluate design changes to a flight deck. These design changes are used for at least one of modification, reconfiguration, refurbishment, and other maintenance or service to the flight deck of aircraft 1700.

Thus, the illustrative examples provide a method, apparatus, system, and computer program product for collecting engineering data. In one illustrative example, a method is used for collecting engineering data. A simulation data stream output from a simulation of an aircraft is received. A number of desired dynamic properties of a physical engineering control in the simulation is identified from the simulation data stream. A physical training control in a training simulator that is an equivalent of the physical engineering control is identified. A number of current dynamic properties is determined for the physical training control. Commands are sent to the physical training control using a difference between the number of current dynamic properties and the number of desired dynamic properties and a feedback controller. Engineering data is collected from the training simulator running of the simulation.

With the ability to use training simulators to collect engineering data, engineering data can be collected from larger numbers of pilots or other crewmembers without needing to purchase or place engineering simulators in locations were training simulators are already present. In these examples, the physical training controls are controlled in a manner that provides a level of fidelity to simulate the performance of the actual physical control in the flight deck of an aircraft. In this manner, more accurate collection of engineering data is possible as compared to using data from running simulations using training simulation software. The illustrative examples also enable continuing to use the training simulators for training.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. An engineering simulation system comprising:
a computer system; and
a flight deck evaluation manager located in the computer system, wherein the flight deck evaluation manager is configured to perform operations comprising:
receiving a simulation data stream output from a simulation of an aircraft;
identifying a number of desired dynamic properties of a physical engineering control in the simulation from the simulation data stream;
identifying a physical training control in a training simulator that is an equivalent of the physical engineering control;
determining a number of current dynamic properties for the physical training control;
sending commands to the physical training control using a difference between the number of current dynamic properties and the number of desired dynamic properties and a feedback controller; and
collecting engineering data from the training simulator running of the simulation.

2. The engineering simulation system of claim 1, wherein the simulation includes a number of changes to a configuration of a flight deck and wherein flight deck evaluation controller is configured to perform the operations comprising:
analyzing the engineering data obtained from running the simulation on the training simulator to determine whether the number of changes meets number of performance metrics.

3. The engineering simulation system of claim 2, wherein the number of changes is selected from at least one of a message change on a display; a different flight display device; or different information on a current flight display device; a user interface change on the display; or a change to a hardware controller.

4. The engineering simulation system of claim 1, wherein in sending the commands, the flight deck evaluation controller is configured to perform the operations comprising:
determining an error from the difference between the number of current dynamic properties and the number of desired dynamic properties using the feedback controller;
selecting a command to cause the number of current dynamic properties to change towards the number of desired dynamic properties; and
sending the command to the physical training control.

5. The engineering simulation system of claim 4, wherein the error is a summation of a current error and a number of prior errors.

6. The engineering simulation system of claim 1, wherein in sending the commands, the flight deck evaluation controller is configured to perform the operations comprising:
sending the commands to the physical training control using the difference between the number of current dynamic properties and the number of desired dynamic properties, a safety check for the number of current dynamic properties, and the feedback controller.

7. The engineering simulation system of claim 1, wherein the feedback controller is selected from at least one of a proportion-integral-derivative controller, a proportional controller, or a neural network controller.

8. The engineering simulation system of claim 1, wherein the number of dynamic properties is selected from at least one of a movement, a speed of the movement, a resistance to being moved by a human operator, a back drivability from external forces, a dampening, a vibration, tactile feedback, or a position.

9. The engineering simulation system of claim 1, wherein the physical training control is selected from a group comprising a physical control, back driven control, an auto throttle, a speed brake, a wheel, a column, pedals, an inceptor, a side stick, thrust control levers, a trim control , and a flap lever.

10. The engineering simulation system of claim 1, wherein the training simulator is selected from a group comprising a full flight simulator and a flight training device.

11. The engineering simulation system of claim 1, wherein the engineering data is selected from at least one of a video, an audio, flight dynamics data, control system data, propulsion data, human machine interface data, control input positions, actuator displacements, system response times, or human operator data.

12. A method for collecting engineering data, the method comprising:
receiving a simulation data stream output from a simulation of an aircraft;
identifying a number of desired dynamic properties of a physical engineering control in the simulation from the simulation data stream;
identifying a physical training control in a training simulator that is an equivalent of the physical engineering control;
determining a number of current dynamic properties for the physical training control;
sending commands to the physical training control using a difference between the number of current dynamic properties and the number of desired dynamic properties and a feedback controller; and
collecting the engineering data from the training simulator running of the simulation.

13. The method of claim 12, wherein the simulation includes a number of changes to a configuration of a flight deck and further comprising:
analyzing the engineering data obtained from running the simulation on the training simulator to determine whether the change meets a number of performance metrics.

14. The method of claim 13, wherein the number of changes is selected from at least one of a message change on a display; a different flight display device; or different information on a current flight display device; a user interface change on the display; or a change to a hardware controller.

15. The method of claim 12, wherein sending the commands comprises:
determining an error from the difference between the number of current dynamic properties and the number of desired dynamic properties;
selecting a command to cause the number of current dynamic properties to change towards the number of desired dynamic properties; and
sending the command to the physical training control.

16. The method of claim 15, wherein the error is a summation of a current error and a number of prior errors.

17. The method of claim 12, wherein sending the commands comprises:
sending the commands to the physical training control using the difference between the number of current dynamic properties and the number of desired dynamic properties, a safety check for the number of current dynamic properties, and the feedback controller.

18. The method of claim 12, wherein the feedback controller is selected from at least one of a proportion-integral-derivative controller, a proportional controller, and a neural network controller.

19. The method of claim 12, wherein the number of dynamic properties is selected from at least one of a movement, a speed of the movement, a resistance to being moved by a human operator, a back drivability from external forces, a dampening, a vibration, tactile feedback, or a position.

20. A computer program product for collecting engineering data, the computer program product comprising:
a computer-readable storage media having program instructions embodied therewith, the program instructions executable by a computer system to cause the computer system to:
receive a simulation data stream output from a simulation of an aircraft;
identify a number of desired dynamic properties of a physical engineering control in the simulation from the simulation data stream;
identify a physical training control in a training simulator that is an equivalent of the physical engineering control;
determine a number of current dynamic properties for the physical training control;
send commands to the physical training control using a difference between the number of current dynamic properties and the number of desired dynamic properties and a feedback controller; and
collect the engineering data from the training simulator running of the simulation.
